(19) United States
(12) Patent Application Publication
(10) Pub. No.: US 2015/0130084 A1
(43) Pub. Date: May 14, 2015

(54) PACKAGE STRUCTURE AND METHOD FOR MANUFACTURING THE SAME

(71) Applicant: CHIPMOS TECHNOLOGIES INC., Hsinchu (TW)

(72) Inventor: TSUNG JEN LIAO, HSINCHU (TW)

(73) Assignee: CHIPMOS TECHNOLOGIES INC, Hsinchu (TW)

(21) Appl. No.: 14/246,302

(22) Filed: Apr. 7, 2014

(30) Foreign Application Priority Data
Nov. 13, 2013 (TW) 102141194

(51) Int. Cl. H01L 23/00; H01L 21/306; H01L 23/36

(52) U.S. Cl. CPC H01L 24/05; H01L 24/03; H01L 23/36; H01L 24/94; H01L 21/30604; H01L 2224/02331; H01L 2224/02379; H01L 2224/02317; H01L 2224/0401; H01L 2224/05008; H01L 2224/03464; H01L 2224/03452; H01L 2924/01022
USPC 257/779; 438/612

(57) ABSTRACT

A fan-out package structure including a heat radiating side edge that includes a semiconductor substrate; a bond pad located on the semiconductor substrate; and a redistribution layer connected with the bond pad and located on the semiconductor substrate, wherein an end of the redistribution layer extends to a sidewall of the semiconductor substrate, and the end is coplanar with the sidewall.

### FIELD

The present invention relates to a semiconductor package, and particularly relates to a fan-out package structure having a heat radiating side edge.

### BACKGROUND

In order to meet current requirements for the portability and versatility of computer and consumer electronics products, the size hereof is required to be further reduced as the integration density of integrated circuit chips becomes greater. Due to the limitation of available space, various packaging methods have emerged; for example, the multi-chip module (MCM), flip chip package, three-dimensional (3D) stack package, and wafer level chip scale package (WLCSP). Basically, the concept of the wafer level packaging technology consists of chip scale packaging being executed on wafers. Most of the packaging work, such as directly forming solder balls on an integrated circuit chip, is completed during the wafer stage. This not only omits the chip carrier, such as a substrate or a lead frame in the conventional packaging technology, but also simplifies the packaging process. Therefore, the WLCSP can decrease the package size and has considerable advantages regarding the process and the material costs.

In general, a package structure requires polishing and dicing processes in the backend. In order to radiate the heat that is generated in the operations, a heat sink 5 and thermal paste 7 are attached on the backside of the package structure as shown in FIG. 1. Before assembling the thermal paste 7 and the heat sink 5, a polishing process is required to planarize the backside. However, this method for heat radiation is costly.

In a conventional embodiment, the thermal paste 7 and the heat sink 5 provide a longitudinal direction (an arrow in FIG. 1) for heat dissipation. A portion of the heat dissipates toward the heat sink 5 and the thermal paste 7. Another portion of the heat dissipates toward the substrate through solder balls. However, as the size of chips continues to shrink and the density of chips becomes greater, heat production increases dramatically; thus the cooling method of the conventional embodiment is no longer appropriate.

### SUMMARY

Examples of the present disclosure provide a fan-out package structure having a heat radiating side edge that includes a semiconductor substrate; a bond pad located on the semiconductor substrate; and a redistribution layer connected with the bond pad and located on the semiconductor substrate, wherein an end of the redistribution layer extends to a sidewall of the semiconductor substrate, and in which the end is coplanar with the sidewall.

In some embodiments, the sidewall includes a rough surface.

In some embodiments, the semiconductor substrate has a backside with a rough surface.

In some embodiments, the redistribution layer is located on a periphery of the semiconductor substrate.

Examples of the present disclosure provide a package structure having a heat radiating pattern that includes a semiconductor substrate; a bond pad located on the semiconductor substrate; and a heat radiating pattern located on the semiconductor substrate, wherein the heat radiating pattern includes a redistribution layer connected with the bond pad and located on a periphery of the semiconductor substrate, and in which an end of the redistribution layer is coplanar with a sidewall of the semiconductor substrate.

In some embodiments, the heat radiating pattern is a circular structure surrounding the periphery of the semiconductor substrate.

Examples of the present disclosure provide a method for manufacturing a fan-out package structure having a heat radiating side edge that includes providing a semiconductor substrate having a bond pad on a front side of the semiconductor substrate; forming a first dielectric layer on the front side of the semiconductor substrate; and forming a redistribution layer connected with the bond pad and located on the first dielectric layer and periphery of the semiconductor substrate, wherein an end of the redistribution layer is coplanar with a sidewall of the semiconductor substrate.

In some embodiments, the method further includes forming a protection layer on the front side of the semiconductor substrate, wherein a backside of the semiconductor substrate and the sidewall are exposed.

In some embodiments, the method further includes immersing the semiconductor substrate in an etching solution so as to wet micro etch the backside and the sidewall.

In some embodiments, the method further includes electroless plating the backside and the sidewall.

In some embodiments, the method further includes forming a protection layer on the backside of the semiconductor substrate.

In some embodiments, the method further includes immersing the semiconductor substrate in an etching solution so as to wet micro etch the sidewall.

In some embodiments, the method further includes electroless plating the sidewall.

### BRIEF DESCRIPTION OF THE DRAWINGS

Aspects of the present disclosure are described with reference to the accompanying figures. It is emphasized that, in accordance with the standard practice in the industry, various features are not drawn to scale. In fact, the dimensions of the various features may be arbitrarily increased or reduced for clarity of discussion.

FIG. 1 is an illustration of a prior art.

FIG. 2 is a schematic cross-sectional view of a fan-out package structure having a heat radiating side edge according to an embodiment of the present invention.

FIG. 3 is a schematic cross-sectional view of a fan-out package structure having a heat radiating side edge according to another embodiment of the present invention.

FIG. 4 is a schematic cross-sectional view of a fan-out package structure having a heat radiating side edge according to still another embodiment of the present invention.

FIG. 5 is a schematic cross-sectional view of a fan-out package structure having a heat radiating side edge according to yet another embodiment of the present invention.

FIG. 6 is a top view of package structures having a heat radiating pattern according to yet another embodiment of the present invention.

FIGS. 7-8 are process flows of forming a sidewall with a rough surface according to another embodiment of the present disclosure.

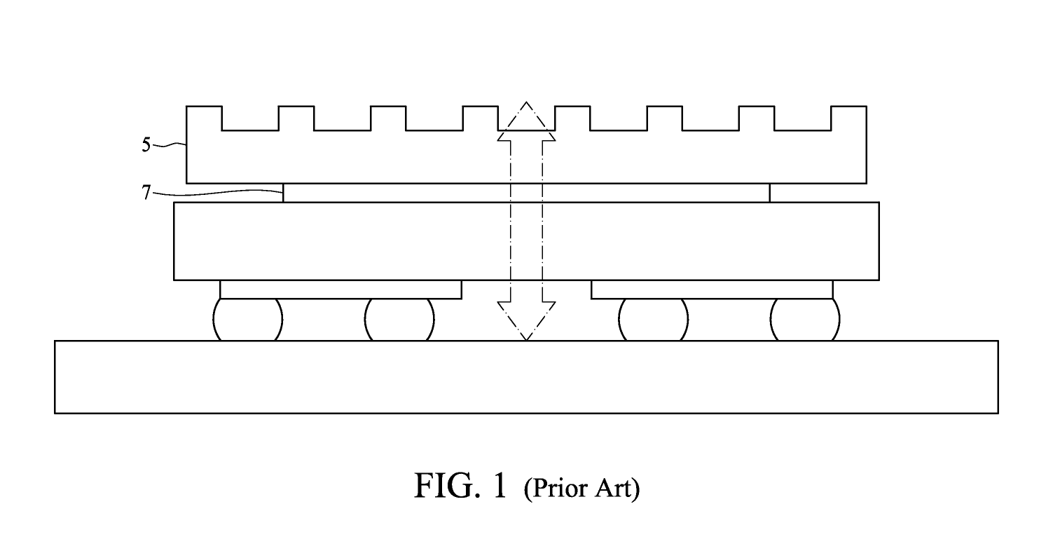

### DETAILED DESCRIPTION OF THE INVENTION

The making and using of various embodiments of the disclosure are discussed in detail below. It should be appreciated, however, that the embodiments provide many applicable inventive concepts that can be embodied in a wide variety of specific contexts. The specific embodiments discussed are merely illustrative, and do not limit the scope of the disclosure.

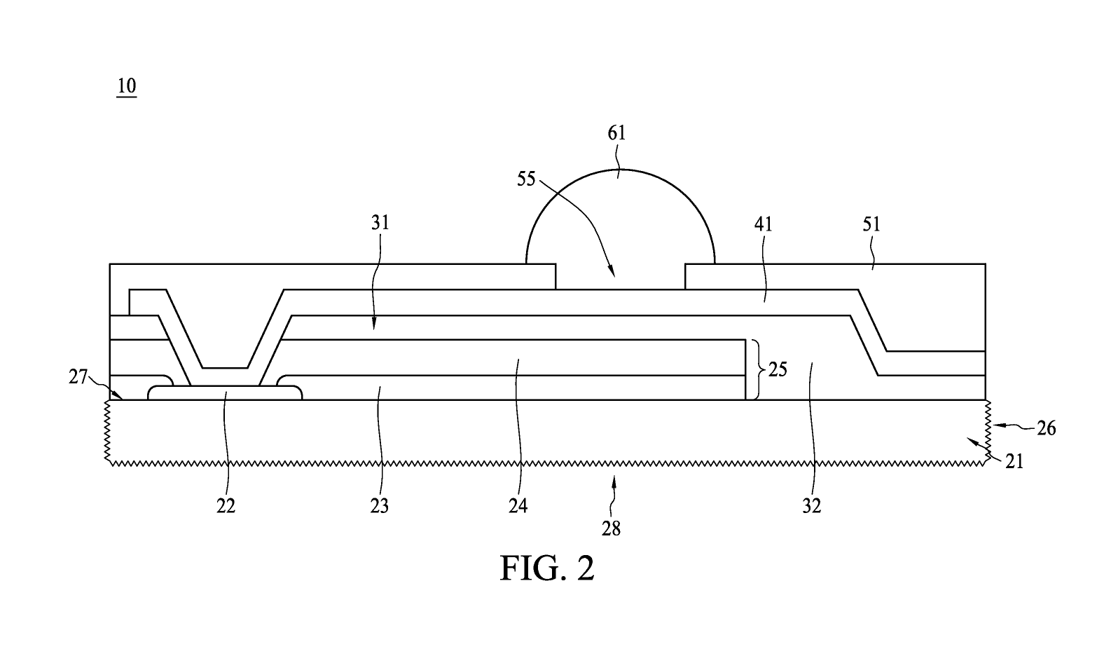

FIG. 2 is a schematic cross-sectional view of a fan-out package structure 10 having a heat radiating side edge according to an embodiment of the present invention. The package structure 10 includes a semiconductor substrate 21, a bond pad 22, a passivation layer 23, a pattern layer 24, a first dielectric layer 31, a redistribution layer (RDL) 41, a second dielectric layer 51, and a solder ball 61. The semiconductor substrate 21 includes a sidewall 26 and a backside 28. The sidewall 26 and the backside 28 include a rough surface. The first dielectric layer 31 includes an extended dielectric layer 32. A side edge of the passivation layer 23 and a side edge of the pattern layer 24 form an end surface 25.

In some embodiments, as shown in FIG. 2, the bond pad 22 is located on the semiconductor substrate 21. The passivation layer 23 is located on the bond pad 22. The passivation layer 23 has an opening to expose a portion of the bond pad 22. The pattern layer 24 is located on the passivation layer 23. Similarly, the pattern layer 24 also has an opening to expose the portion of the bond pad 22. The opening of the passivation layer 23 is aligned with the opening of the bond pad 22. The first dielectric layer 31 is located on the passivation layer 24. The first dielectric layer 31 covers the pattern layer 24 and the end surface 25. In addition, the first dielectric layer 31 extends to the sidewall 26 so as to form the extended dielectric layer 32. The extended dielectric layer 32 is located on the semiconductor substrate 21. Further, an end of the extended dielectric layer 32 is coplanar with the sidewall 26. The redistribution layer 41 connects to the bond pad 22 and is located on the semiconductor substrate 21. Furthermore, an end of the redistribution layer 41 extends to the sidewall 26 of the semiconductor substrate 21. The end of the redistribution layer 41 is coplanar with the sidewall 26.

In this embodiment, the second dielectric layer 51 covers the redistribution layer 41. The second dielectric layer 51 extends to the sidewall 26. In addition, an end of the second dielectric layer 51 is coplanar with the sidewall 26. The second dielectric layer 51 includes an opening 55. The opening 55 exposes a portion of the redistribution layer 41. The opening 55 serves as a position for the solder ball 61. In some embodiments, an under bump metallization (UBM, not shown) is formed in the opening 55. Later, the solder ball 61 is formed on the under bump metallization. Therefore, the solder ball 61 electrically connects to the redistribution layer 41.

The redistribution layer 41 not only serves as an internal and electrical connection of the package structure 10, but also provides a heat radiating path. The solder ball 61 and the bond pad 22 are major heat generating regions. The electrical transmission will bring out heat generation. Effectively, the redistribution layer 41 provides a thermally conductive path. The redistribution layer 41 transmits not only electrical signals, but also heat. Furthermore, the redistribution layer 41 is made of metal that provides higher thermal conductivity than dielectric materials. During electrical transmission, the heat is guided to a periphery of the semiconductor substrate 21 and the sidewall 26 by paths of the redistribution layer 41. Further, the redistribution layer 41 radiates the heat by convection or conduction with external environments so that heat dissipation is accelerated.

In some embodiments, the sidewall 26 is a rough surface. The semiconductor substrate 21 bears heat generated by internal circuits. Effectively, the rough surface of the sidewall 26 increases surface area for heat that is radiated. The rough surface of the sidewall 26 accelerates convection or conduction with external environments so that the heat is removed from the semiconductor substrate 21. The sidewall 26 with the rough surface prevents overheating of the semiconductor substrate 21, wherein the overheating would cause electrical deviation or noise. Moreover, the sidewall 26 with the rough surface provides a laterally cooling mechanism. In other words, the sidewall 26 provides a lateral heat radiating path for heat dissipation. In some embodiments, the rough surface is plated with metal having a better thermal conductivity so as to increase convection with outside environments.

Further, in some embodiments, the sidewall 26 and the backside 28 are both rough surfaces so as to increase surface area for heat radiating. With the redistribution layer 41 and the rough surfaces, radiation ability of the package structure 10 is improved. In comparison to prior arts, package structures of prior arts require a polishing or planarization for the backside and attachment of a heat sink. In the present disclosure, the backside 28 omits additional polishing or planarization, and thereby reduces the cost and complexity of the manufacturing process. Further, the backside 28 is performed to form a rough surface instead of polishing. As such, the backside 28 with the rough surface serves as a heat radiating path for the heat of the semiconductor substrate 21. In addition, the backside 28 occupies most of the surface of the package structure 10 so that the backside 28 provides a large area for heat dissipation. The backside 28 with the rough surface provides a longitudinally cooling mechanism that replaces the heat sink. In some embodiments, the backside 28 with the rough surface is plated with metal having a better thermal conductivity so as to increase convection with outside environments.

Manufacturing methods of the package structure 10 in FIG. 2 are described as below. In the present disclosure, a semiconductor substrate 21 is provided, and the semiconductor substrate 21 may be, for example, a silicon substrate, a diced chip or a printed circuit board (PCB). A bond pad 22 is formed on a front side 27 of the semiconductor substrate 21. The bond pad 22 is formed by, for example, chemical vapor deposition (CVD), plasma enhanced chemical vapor deposition (PECVD) or physical vapor deposition (PVD) such as sputtering or vapor deposition. The bond pad 22 is made of metal, such as silver, copper, or some other conductive metal used in packaging.

A passivation layer 23 is formed on the semiconductor substrate 21. Later, the passivation layer 23 is patterned to expose a portion of the bond pad 22. The passivation layer 23 is made of passivation materials, such as silicon oxide or nitride. The passivation layer 23 is formed by sputtering, vapor deposition or coating. Later, a patterned photoresist layer or a mask is formed on the passivation layer 23. An etching process is performed to expose a portion of the bond pad 22. Next, the patterned photoresist layer or the mask is removed.

Afterward, a pattern layer 24 is deposited on the passivation layer 23. The pattern layer 24 includes a predetermined opening above the bond pad 22. The pattern layer 24 is made of a polymer dielectric layer, but is not limited thereto. The pattern layer 24 is formed by coating. Liquid polymer is uniformly coated on the semiconductor substrate 21 by a spin coating machine. A mask shields some predetermined positions for openings.

An exposure process is performed. Later, a development process is performed to remove unexposed regions to form the predetermined opening above the bond pad 22. Further, the liquid polymer is baked by an oven so that the polymer is solidified to form the pattern layer 24. A side edge of the passivation layer 23 and a side edge of the pattern layer 24 form an end surface 25. In other words, an end of the passivation layer 23 is coplanar with an end of the pattern layer 24 so as to form the end surface 25.

Subsequently, a first dielectric layer 31 is formed on the front side 27 of the semiconductor substrate 21. The first dielectric layer 31 includes, for example, an oxide layer, a nitride layer or a polymer layer. The first dielectric layer 31 is formed by a variation method, such as CVD, PVD or a spin coating process, depending on different requirements. The first dielectric layer 31 covers the pattern layer 24 and a portion of the semiconductor substrate 21. The first dielectric layer 31 includes an extended dielectric layer 32. The extended dielectric layer 32 covers the end surface 25 and extends to the sidewall 26. An end of the extended dielectric layer 32 is coplanar with the sidewall 26. The first dielectric layer 31 conforms to height difference of layers so as to form an approximately trapezoidal distribution.

Then, a redistribution layer 41 connected with the bond pad 22 is formed. The redistribution layer 41 is located on the first dielectric layer 31 and a periphery of the semiconductor substrate 21. An end of the redistribution layer 41 is coplanar with the sidewall 26 of the semiconductor substrate 21. The redistribution layer 41 provides a current path and a heat transmission path. The redistribution layer 41 dissipates internal heat generated by the electrical connection to the periphery regions. The redistribution layer 41 includes metal, such as copper, silver, palladium, gold or alloys thereof. The redistribution layer 41 is formed by a variation method, such as CVD or PVD.

A second dielectric layer 51 is formed on the redistribution layer 41. Later, a photoresist layer or a mask is patterned to define an opening 55. An etching process, such as a dry etch, a wet etch or an optical etch, is performed to expose a portion of the redistribution layer 41. In some embodiments, an under bump metallization (UBM) is formed in the opening 55. The UBM includes at least two metal layers, an adhesive layer and a seed layer. The adhesive layer directly connects with the redistribution layer 41. The adhesive layer is usually made of titanium or titanium tungsten (TiW) in order to provide a better mechanically connection and better adhesion between the redistribution layer 41 and a solder ball 61. The seed layer is made of metal, such as gold, copper, nickel or alloy thereof. The UBM is formed by a metal sputtering process, vapor deposition process or printing process.

Next, the solder ball 61 is formed on the UBM or directly on the redistribution layer 41. In this embodiment, the solder ball 61 is made of tin. The solder ball 61 is formed by, for example, screen printing, vapor deposition, electroplating, dropping ball, or spray ball process.

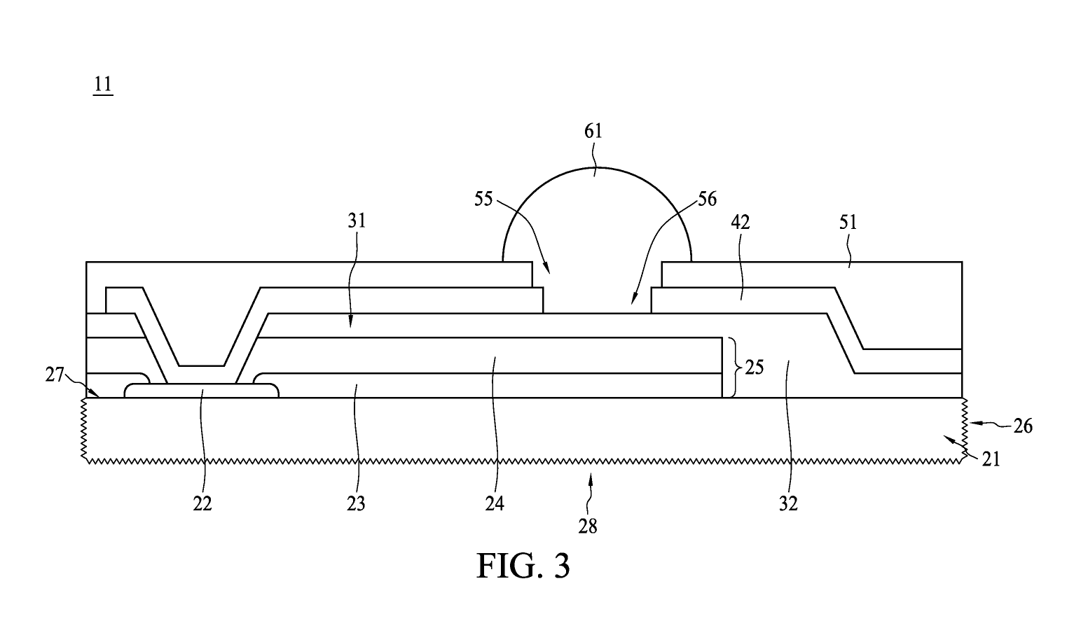

FIG. 3 is a schematic cross-sectional view of a fan-out package structure 11 having a heat radiating side edge according to another embodiment of the present invention. The package structure 11 is similar to the structure and manufacturing method of the package structure 10. The difference between the package structure 11 and the package structure 10 is a patterned redistribution layer 42. The patterned redistribution layer 42 includes an opening 56. The opening 56 aligns with the opening 55. The two openings provide the solder ball 61 with a deeper accommodating space so that the solder ball 61 is more stable. Meanwhile, the patterned redistribution layer 42 provides a heat radiating path for lateral heat dissipation. Effectively, by means of the sidewall 26 and the backside 28 with the rough surfaces, the package structure 11 has better radiation efficiency.

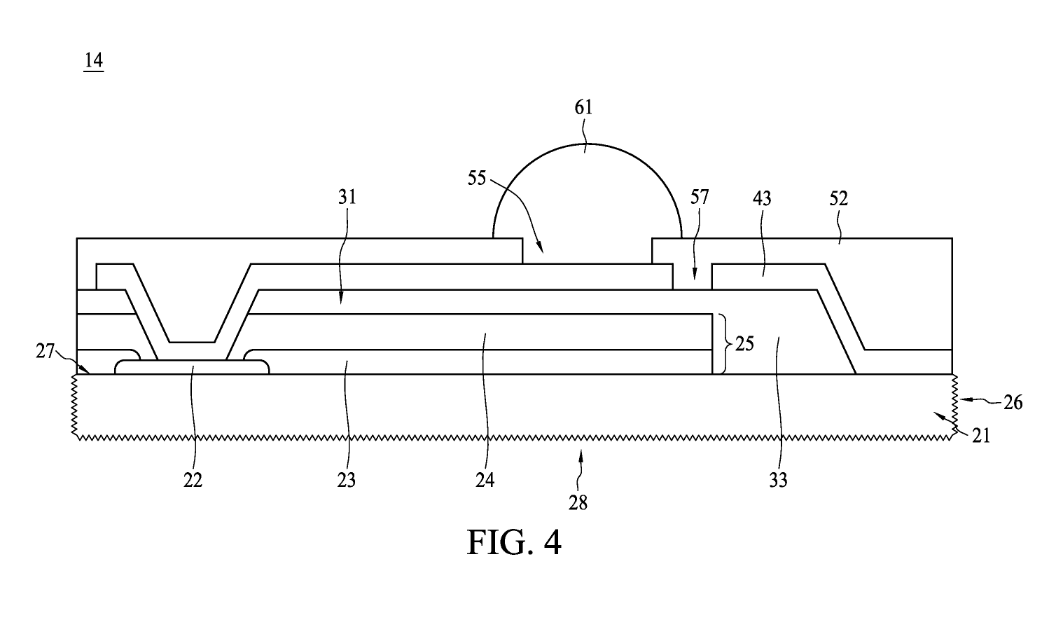

FIG. 4 is a schematic cross-sectional view of a fan-out package structure 14 having a heat radiating side edge according to another embodiment of the present invention. The package structure 14 is similar to the composition and manufacturing method of the package structure 10. The difference between the package structure 10 and the package structure 14 is a redistribution layer 43 having an opening 57. The opening 57 is away from the opening 55. In addition, the opening 57 is filled with a second dielectric layer 52. Thus, the opening 57 serves as an obstruction to block the electrical connection between the semiconductor substrate 21 and outside environments. Further, the first dielectric layer 31 includes an extended dielectric layer 33. The extended dielectric layer 33 covers the end surface 25 and a portion of the semiconductor substrate 21. Particularly, the extended dielectric layer 33 covers a periphery of the semiconductor substrate 21. An end of the extended dielectric layer 33 is not coplanar with the sidewall 26. That is to say, ends of the extended dielectric layer 33 are not coplanar with the sidewall 26. The end of the extended dielectric layer 33 is in contact with the periphery of the semiconductor substrate 21. The redistribution layer 43 is also in contact with another periphery of the semiconductor substrate 21. If there is more contact area between the semiconductor substrate 21 and the redistribution layer 43, more heat can be removed. At the same time, by means of the sidewall 26 and the backside 28 with the rough surfaces, the package structure 14 has better radiation efficiency. By having the sidewall 26 and the backside 28 in place, the heat generated from the semiconductor substrate 21 radiates to outside environments.

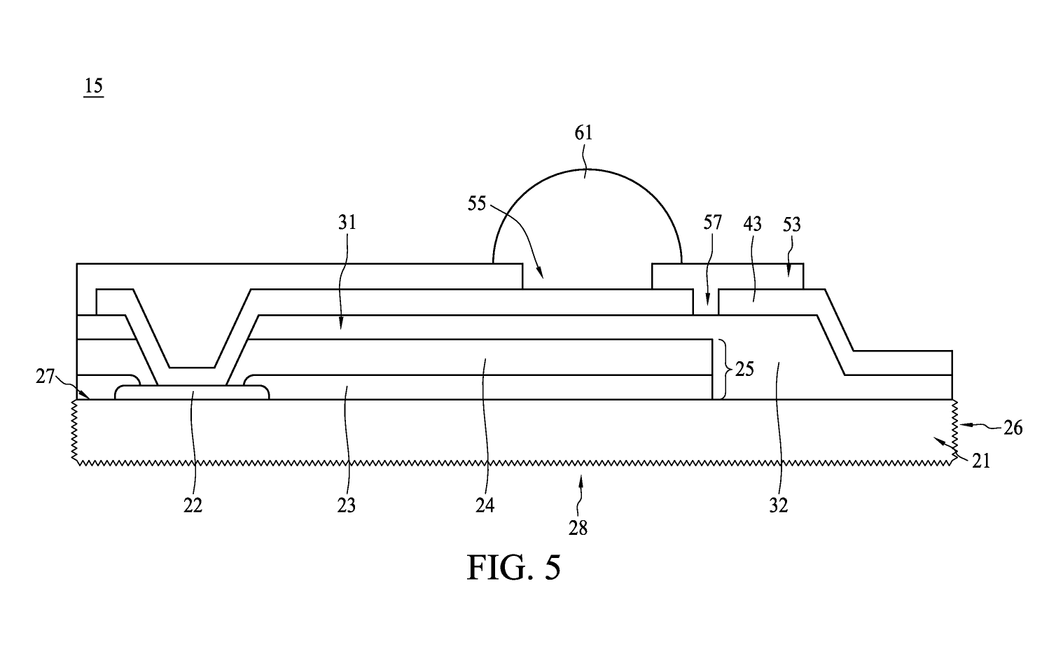

FIG. 5 is a schematic cross-sectional view of a fan-out package structure 15 having a heat radiating side edge according to another embodiment of the present invention. The package structure 15 is similar to the composition and manufacturing method of the package structure 10. The difference between the package structure 10 and the package structure 15 is a redistribution layer 43 having an opening 57. The opening 57 is away from the opening 55. In addition, the opening 57 is filled with a second dielectric layer 53. Thus, the opening 57 serves as an obstruction to block the electrical connection between the semiconductor substrate 21 and outside environments. In addition, the second dielectric layer 53 covers a portion of the redistribution layer 43. An end of the second dielectric layer 53 is not coplanar with the sidewall 26. Accordingly, an end portion of the redistribution layer 43 is exposed to outside environments. The redistribution layer 43 increases convection with the outside environments so as to accelerate heat dissipation. Meanwhile, by means of the sidewall 26 and the backside 28 with the rough surfaces, the package structure 14 has better radiation efficiency.

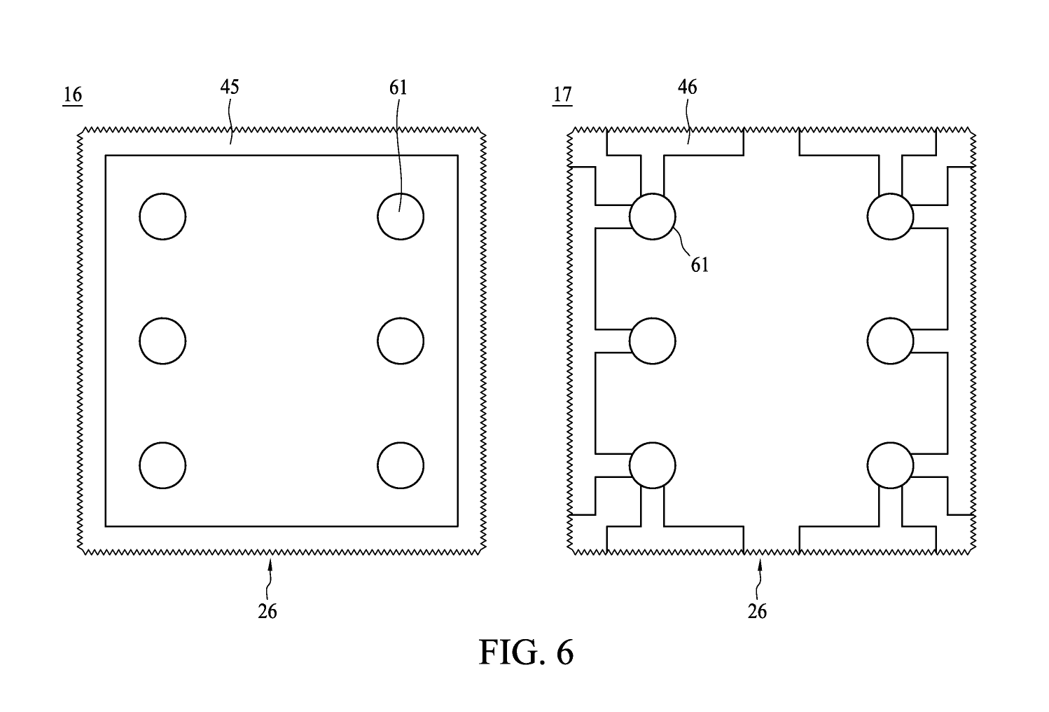

FIG. 6 is a top view of package structures 16 and 17 having a heat radiating pattern according to another embodiment of the present invention. As shown in a left diagram in FIG. 6, a redistribution layer is located on a periphery of the semiconductor substrate 21 and forms a heat radiating pattern 45. The heat radiating pattern 45 is located on a semiconductor substrate or a chip. The heat radiating pattern 45 is made of a redistribution layer connected with inner bond pads. Further, the heat radiating pattern 45 is located on a periphery of the semiconductor substrate 21. Ends of the heat radiating pattern 45 are coplanar with the sidewall 26 of the semiconductor substrate 21. On the other hand, the ends of the heat radiating pattern 45 are coplanar with the sidewall 26. In this embodiment, the heat radiating pattern 45 is a circular structure continuously surrounding the periphery of the semiconductor substrate 21. The package structure 16 includes a solder ball 61 that has a relative position as shown in FIG. 6. In some embodiments, the heat radiating pattern 45 electrically connects with the solder ball 61 internally. In some embodiments, the heat radiating pattern 45 does not electrically connect with the solder ball 61. The heat radiating pattern 45 provides a lateral heat radiating path for heat dissipation. Meanwhile, the sidewall 26 having a rough surface also provides a lateral heat radiating path and improves radiation efficiency.

As shown in a right diagram in FIG. 6, a top view of a package structure 17 illustrates a heat radiating pattern according to another embodiment of the present invention. A redistribution layer is located on a periphery of the semiconductor substrate 21 and forms a heat radiating pattern 46. The heat radiating pattern 46 externally connects to the solder ball 61 as shown in FIG. 6. In operation, the heat radiating pattern 46 is configured to guide heat generated by the semiconductor substrate 21 to periphery regions. The heat radiating pattern 46 is in a discontinuous configuration, but is not limited thereto. In addition, the configuration of the heat radiating pattern 46 determines paths for heat dissipation. The heat radiating pattern 46 is located on the semiconductor substrate 21. Further, ends of the heat radiating pattern 46 are coplanar with the sidewall 26 of the semiconductor substrate 21. Meanwhile, the sidewall 26 having a rough surface also provides a lateral heat radiating path and improves radiation efficiency. By convection of the heat radiating pattern 46 with outside environments, the heat generated by the solder ball 61 or the semiconductor substrate 21 is radiated to a periphery of the package structure 17 during operation. The heat radiating pattern 46 is made of metal having a high thermal conductivity. Effectively, the heat radiating pattern 46 serves as a path for heat transmission and heat dissipation. Meanwhile, the sidewall 26 with a rough surface provides central heat to radiate laterally so as to improve radiation efficiency. In some embodiments, the rough surface of the sidewall 26 is plated with metal in order to enhance the radiation efficiency.

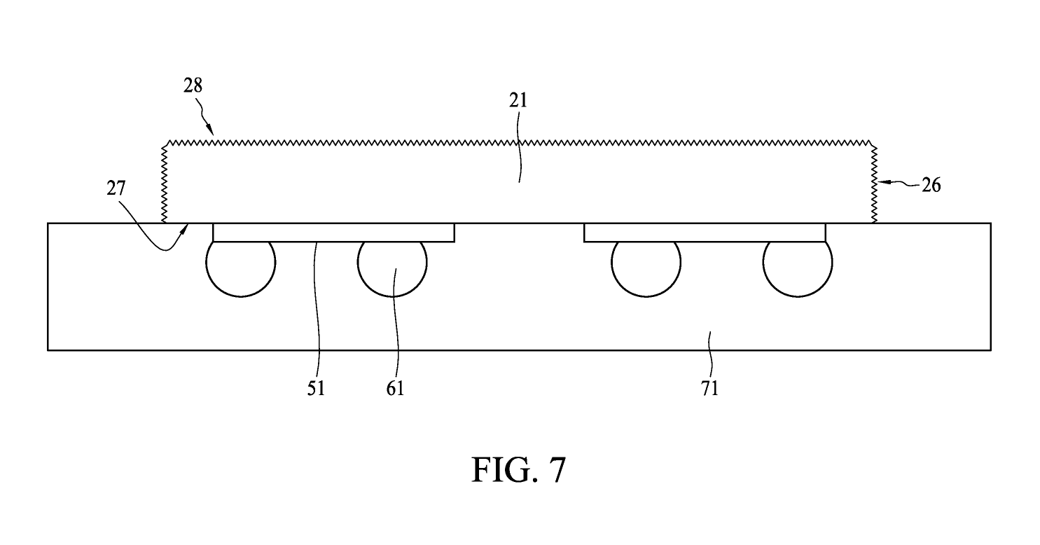

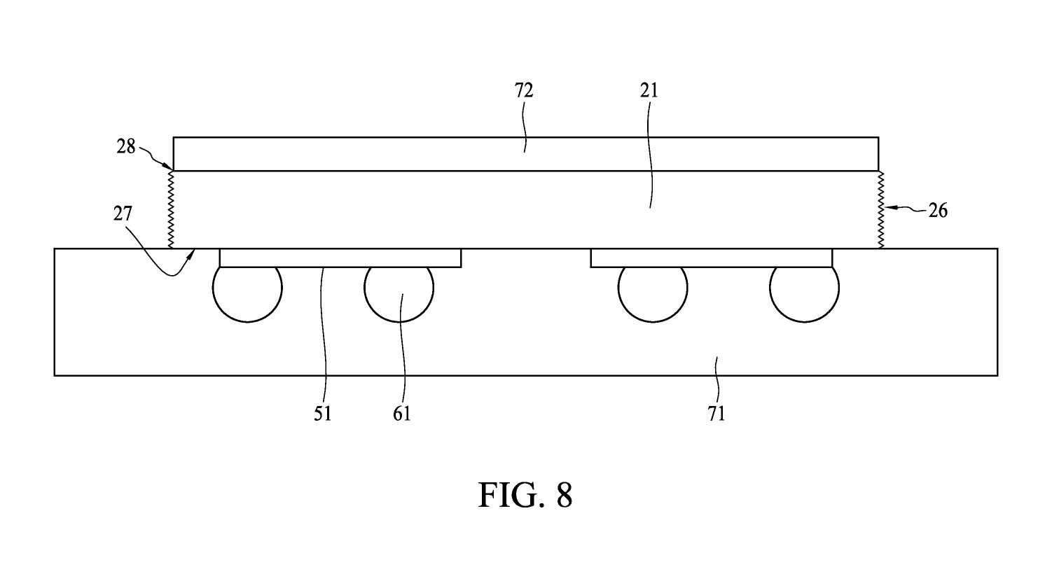

FIGS. 7-8 are process flows of forming the sidewall 26 with a rough surface according to another embodiment of the present disclosure. Each plot refers to a step of the manufacturing process. After the solder ball 61 is formed, a protection layer 71 is formed on the front side 27 of the semiconductor substrate 21 as shown in FIG. 7. Only the backside 28 and the sidewall 26 are exposed. For example, the protection layer 71 is a dry film, a photoresist layer or a tape. Subsequently, the semiconductor substrate 21 is immersed in an etching solution. The backside 28 and the sidewall 26 are wet micro etched so as to form a rough surface. In some embodiments, the backside 28 and the sidewall 26 are electroless plated after formation of the rough surface. The plated metal attaches to the backside 28 and the sidewall 26 so that radiation efficiency is increased.

The backside 28 with a rough surface serves as a heat radiating path for heat dissipation. In comparison, the present disclosure omits backside grinding, thermal paste and attachments of a heat sink; thereby significantly reducing the cost and complexity of the manufacturing process.

In some embodiments, after the solder ball 61 is formed, a protection layer 71 is formed on the front side 27 of the semiconductor substrate 21. In addition, a protection layer 72 is formed on the backside 28 as shown in FIG. 8. Only the sidewall 26 is exposed. For example, the protection layers 71 and 72 are a dry film, a photoresist layer or a tape. Subsequently, the semiconductor substrate 21 is immersed in an etching solution. The sidewall 26 is wet micro etched so as to form a rough surface. In some embodiments, the sidewall 26 is electroless plated after formation of the rough surface. The plated metal attaches to the sidewall 26 so that radiation efficiency is increased.

The above description includes exemplary operations, but these operations are not necessarily required to be performed in the order shown. Operations may be added, replaced, changed order, skipped, and/or eliminated as appropriate, in accordance with the spirit and scope of the disclosure. Accordingly, the scope of the disclosure should be determined with reference to the following claims, along with the full scope of equivalences to which such claims are entitled.

What is claimed is:

1. A fan-out package structure including a heat radiating side edge, comprising:
a semiconductor substrate;
a bond pad located on the semiconductor substrate; and
a redistribution layer connected with the bond pad and located on the semiconductor substrate, wherein an end of the redistribution layer extends to a sidewall of the semiconductor substrate, and the end is coplanar with the sidewall.

2. The fan-out package structure of claim 1, wherein the sidewall comprises a rough surface.

3. The fan-out package structure of claim 1, wherein the semiconductor substrate has a backside with a rough surface.

4. The fan-out package structure of claim 1, wherein the redistribution layer is located on a periphery of the semiconductor substrate.

5. A package structure including a heat radiating pattern, comprising:
a semiconductor substrate;
a bond pad located on the semiconductor substrate; and
a heat radiating pattern located on the semiconductor substrate, wherein the heat radiating pattern comprises a redistribution layer connected with the bond pad and located on the periphery of the semiconductor substrate, and an end of the redistribution layer is coplanar with a sidewall of the semiconductor substrate.

6. The package structure of claim 5, wherein the heat radiating pattern is a circular structure surrounding the periphery of the semiconductor substrate.

7. The package structure of claim 5, wherein the sidewall comprises a rough surface.

8. The package structure of claim 5, wherein the semiconductor substrate has a backside with a rough surface.

9. A method for manufacturing a fan-out package structure including a heat radiating side edge, comprising:
providing a semiconductor substrate including a bond pad on a front side of the semiconductor substrate;
forming a first dielectric layer on the front side of the semiconductor substrate; and
forming a redistribution layer connected with the bond pad and located on the first dielectric layer and a periphery of the semiconductor substrate, wherein an end of the redistribution layer is coplanar with a sidewall of the semiconductor substrate.

10. The method of claim 9, further comprising forming a protection layer on the front side of the semiconductor substrate, wherein a backside of the semiconductor substrate and the sidewall are exposed.

11. The method of claim 9, further comprising immersing the semiconductor substrate in an etching solution so as to wet micro etch the backside and the sidewall.

12. The method of claim 11, further comprising electroless plating the backside and the sidewall.

13. The method of claim 10, further comprising forming a protection layer on the backside of the semiconductor substrate.

14. The method of claim 13, further comprising immersing the semiconductor substrate in an etching solution so as to wet micro etch the sidewall.

15. The method of claim 14, further comprising electroless plating the sidewall.
